(19) United States
(12) Patent Application Publication
(10) Pub. No.: US 2026/0177632 A1
(43) Pub. Date: Jun. 25, 2026

(54) BATTERY CURRENT MEASUREMENT IN AN ELECTRICAL CIRCUIT

(71) Applicant: Qorvo US, Inc., Greensboro, NC (US)

(72) Inventors: Nadim Khlat, Ceret (FR); Philippe Gorisse, Brax (FR); Christopher Truong Ngo, Queen Creek, AZ (US); Jean-Frederic Chiron, Tournefeuille (FR)

(21) Appl. No.: 19/126,711

(22) PCT Filed: Nov. 9, 2023
(86) PCT No.: PCT/US2023/079178

§ 371 Date: May 2, 2025

Related U.S. Application Data
(60) Provisional application No. 63/384,345, filed on Nov. 18, 2022.
(60) Provisional application No. 63/384,351, filed on Nov. 18, 2022.
(60) Provisional application No. 63/466,799, filed on May 16, 2023.

(51) Int. Cl. G01R 31/392; G01R 31/3842; G01R 31/396

(52) U.S. Cl. CPC G01R 31/392; G01R 31/3842; G01R 31/396

(57) ABSTRACT

Battery current measurement in an electrical circuit is provided. In a non-limiting example, the electrical circuit under measurement can be a wireless communication circuit powered by a battery. In embodiments disclosed herein, the electrical circuit includes one or more current sense circuits each coupled to a measurement node(s) (e.g., switch and low-dropout regulator) that is directly coupled to the battery. Each of the current sense circuits can measure an average battery current flowing through the measurement node(s) during a selected measurement period. A measurement output circuit is provided in the electrical circuit to summarize the average battery current measured by each of the current sense circuits to provide a snapshot of a total average battery current in the electrical circuit. Accordingly, the electrical circuit may take appropriate actions to prolong battery life.

### RELATED APPLICATIONS

This application claims the benefit of U.S. provisional patent application Ser. No. 63/384,345, filed on Nov. 18, 2022, U.S. provisional patent application Ser. No. 63/384,351, filed on Nov. 18, 2022, and U.S. provisional patent application Ser. No. 63/466,799, filed on May 16, 2023, the disclosures of which are hereby incorporated herein by reference in their entireties.

### FIELD OF THE DISCLOSURE

The technology of the disclosure relates generally to battery current measurement in an electrical circuit, such as a wireless communication circuit.

### BACKGROUND

Fifth generation (5G) new radio (NR) (5G-NR) has been widely regarded as the next generation of wide-area wireless communication technology beyond the fourth generation (4G) technology. In this regard, a wireless communication device capable of supporting the 5G-NR wireless communication technology is expected to achieve higher data rates, improved coverage range, enhanced signaling efficiency, and reduced latency across a wide range of radio frequency (RF) bands, which include a low-band (below 1 GHz), a mid-band (1 GHz to 6 GHz), and a high-band (above 24 GHz). Moreover, the wireless communication device may still support the legacy 3G and 4G technologies for backward compatibility.

In addition to the wide-area wireless communication technologies above, the wireless communication device is required to support such local area or personal area networking technologies as Wi-Fi, Bluetooth, ultra-wideband (UWB), and so on. Furthermore, the wireless communication device may also need to support such internet-of-things (IoT) applications as keyless car entry, remote garage door opening, contactless payment, mobile boarding passes, and so on. Needless to say, the wireless communication device must also make 911/E911 service accessible under emergency situations.

Notably, the wireless communication device relies on a battery cell (e.g., Li-Ion battery) to power its operations and services. Despite recent advancement in battery technologies, the wireless communication device can run into a low battery situation from time to time. In this regard, it is desirable to accurately measure current flow in the wireless communication device to prevent potential service interruption.

### SUMMARY

Embodiments of the disclosure relate to battery current measurement in an electrical circuit. In a non-limiting example, the electrical circuit under measurement can be a wireless communication circuit powered by a battery. In embodiments disclosed herein, the electrical circuit includes one or more current sense circuits each coupled to a measurement node(s) (e.g., switch and low-dropout regulator) that is directly coupled to the battery. Each of the current sense circuits can measure an average battery current flowing through the measurement node(s) during a selected measurement period. A measurement output circuit is provided in the electrical circuit to summarize the average battery current measured by each of the current sense circuits to provide a snapshot of a total average battery current in the electrical circuit. Accordingly, the electrical circuit may take appropriate actions to prolong battery life.

In one aspect, an electrical circuit is provided. The electrical circuit includes multiple measurement nodes. Each of the multiple measurement nodes is coupled directly to a battery. The electrical circuit also includes one or more current sense circuits. Each of the one or more current sense circuits is coupled to a respective one or more of the multiple measurement nodes and configured to measure an average battery current flowing through the respective one or more of the multiple measurement nodes during a selected measurement period. The electrical circuit also includes a measurement output circuit. The measurement output circuit is configured to summarize the average battery current measured by each of the one or more current sense circuits during the selected measurement period.

In another aspect, a method for measuring an average battery current in an electrical circuit is provided. The method includes measuring the average battery current flowing through multiple measurement nodes each coupled directly to a battery during a selected measurement period. The method also includes summarizing the average battery current measured during the selected measurement period.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram illustrating a conventional battery current measurement method;

FIG. 2 is a schematic diagram of an exemplary electrical circuit configured according to embodiments of the present closure to measure a battery current in the electrical circuit;

FIG. 3 is a schematic diagram illustrating a direct-current-direct-current (DC-DC) voltage converter that can be measured as the electrical circuit in FIG. 2 in accordance with the embodiments of the present disclosure;

FIG. 4 is a schematic diagram of an exemplary current sense circuit that can be provided in the electrical circuit in FIG. 2;

FIGS. 5A and 5B are schematic diagrams each illustrating an exemplary measurement output circuit that can be provided in the electrical circuit in FIG. 2 to measure the battery current over an averaging period;

FIGS. 6A and 6B are schematic diagrams providing exemplary illustrations of the averaging period;

FIG. 7 is a schematic diagram of an exemplary user element wherein the electrical circuit of FIG. 2 can be provided; and

FIG. 8 is a flowchart of an exemplary process for measuring an average battery current in an electrical circuit.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to battery current measurement in an electrical circuit. In a non-limiting example, the electrical circuit under measurement can be a wireless communication circuit powered by a battery. In embodiments disclosed herein, the electrical circuit includes one or more current sense circuits each coupled to a measurement node(s) (e.g., switch and low-dropout regulator) that is directly coupled to the battery. Each of the current sense circuits can measure an average battery current flowing through the measurement node(s) during a selected measurement period. A measurement output circuit is provided in the electrical circuit to summarize the average battery current measured by each of the current sense circuits to provide a snapshot of a total average battery current in the electrical circuit. Accordingly, the electrical circuit may take appropriate actions to prolong battery life.

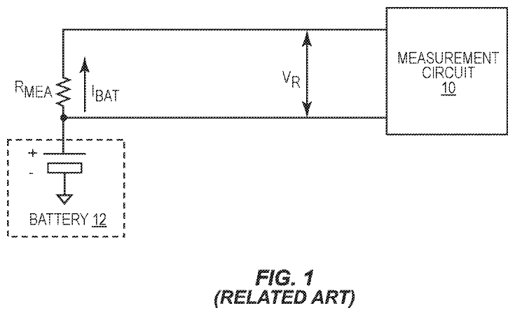

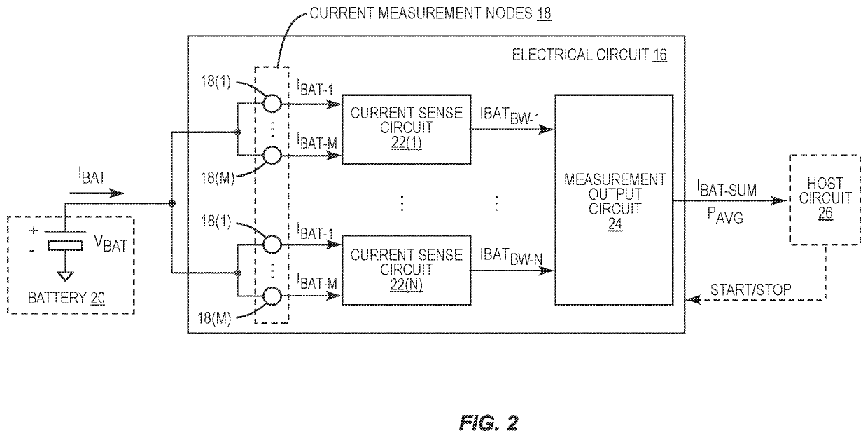

Before discussing the electrical circuit, wherein a battery current can be measured according to the present disclosure, starting at FIG. 2, an overview of a conventional battery measurement method is first provided with reference to FIG. 1.

FIG. 1 is a schematic diagram illustrating a conventional battery current measurement method. Herein, a measurement circuit 10 is configured to measure a battery current IBAT of a battery 12 via a measurement resistor RMEA. More specifically, the measurement circuit 10 first measures a voltage VR across the measurement resistor RMEA and then calculates the battery current IBAT in accordance with the Ohms Law.

An obvious drawback associated with the conventional battery current measurement method is that the measurement resistor RMEA can cause significant insertion loss. As such, it is desirable to measure the battery current without the measurement resistor RMEA to help reduce insertion loss.

In this regard, FIG. 2 is an electrical circuit 16 that can be configured according to embodiments of the present closure to measure a battery current IBAT at multiple measurement nodes 18 that are directly coupled to a battery 20. In context of the present disclosure, the electrical circuit 16 can be any electrical circuit powered by the battery 20, including but not limited to a power management integrated circuit (PMIC), a power amplifier circuit, a transceiver circuit, a radio frontend circuit, and a direct-current-direct-current (DC-DC) voltage converter. In a non-limiting example, the measurement nodes 18 can be switches or low-dropout (LDO) regulators that are coupled to the battery 20 without any intervening circuits and/or components.

As discussed in detail below, the electrical circuit 16 can be configured to measure the battery current IBAT at each of the measurement nodes 18 without employing the measurement resistor RMEA in FIG. 1. As such, it is possible to reduce the insertion loss and improve operating efficiency and performance of the electrical circuit 16.

In an embodiment, the electrical circuit 16 includes multiple current sense circuits 22(1)-22(N) and a measurement output circuit 24. Each of the current sense circuits 22(1)-22(N) is coupled to a respective one or more of the measurement nodes 18. In other words, each of the current sense circuits 22(1)-22(N) is coupled to a respective subset 18(1)-18(M) (M≥1) of the measurement nodes 18. The measurement output circuit 24 may be coupled to a host circuit 26 (e.g., a transceiver circuit) configured to monitor power consumption in the electrical circuit 16. The host circuit 26 may be configured to start and stop such battery current measurements in the electrical circuit 16 either periodically or as needed.

Herein, each of the current sense circuits 22(1)-22(N) is configured to measure a respective one or more average battery currents IBAT-1-IBAT-M flowing through the respective measurement nodes 18(1)-18(M) during a selected measurement period. In a non-limiting example, the selected measurement period can be a time-division multiplexing (TDD) timeslot, a TDD mini-timeslot, or a multiple of the TDD timeslots/mini-timeslots. The measurement output circuit 24, in turn, will summarize the average battery currents IBAT-1-IBAT-M measured by each of the current sense circuits 22(1)-22(N) during the selected measurement period and provide a summarized measurement result IBAT-SUM to the host circuit 26.

In an embodiment, each of the current sense circuits 22(1)-22(N) is further configured to encode the respective average battery currents IBAT-1-IBAT-M, as measured during the selected measurement period, into a respective one of one or more digital measurement words IBAT_{BW-1}-IBAT_{BW-N}. The measurement output circuit 24, in turn, is configured to combine the digital measurement words IBAT_{BW-1}-IBAT_{BW-N} to thereby generate the summarized measurement result I_{BAT-SUM} as a digital summary word I_{BAT-SUM}.

In an embodiment, the measurement output circuit 24 may also determine an average power consumption P_{AVG} during the selected measurement period based on the measured total battery current I_{BAT-SUM} and a voltage V_{BAT} of the battery 20. In an embodiment, the voltage V_{BAT} can be an instantaneous voltage reading of the battery 20 or an average of voltage readings during the selected measurement period.

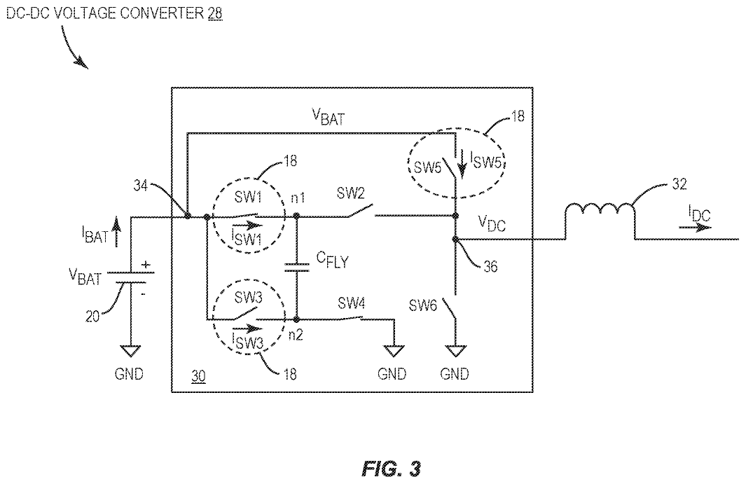

As mentioned earlier, the electrical circuit 16 under measurement can be a DC-DC voltage converter. In this regard, FIG. 3 is a schematic diagram illustrating a DC-DC voltage converter 28 that can be measured as the electrical circuit 16 in FIG. 2 in accordance with the embodiments of the present disclosure. Common elements between FIGS. 2 and 3 are shown therein with common element numbers and will not be re-described herein.

In a non-limiting example, the DC-DC voltage converter 28 includes a multi-level charge pump (MCP) 30 coupled in series to a power inductor 32. The MCP 30 includes an input node 34, an output node 36, a first intermediate node n1, and a second intermediate node n2. The input node 34 is coupled to the battery 20 to receive the battery voltage V_{BAT} and the battery current I_{BAT}. The output node 36 is coupled to the power inductor 32 and outputs a low-frequency voltage V_{DC} as a function of the battery voltage V_{BAT}. The power inductor 32 will, in turn, induce a low-frequency current loc based on the low-frequency voltage V_{DC}.

Specifically, the MCP 30 includes a first switch SW1, a second switch SW2, a third switch SW3, a fourth switch SW4, a fifth switch SW5, and a sixth switch SW6. The first switch SW1 is coupled between the input node 34 and the first intermediate node n1. The second switch SW2 is coupled between the first intermediate node n1 and the output node 36. The third switch SW3 is coupled between the input node 34 and the second intermediate node n2. The fourth switch SW4 is coupled between the second intermediate node n2 and a ground (GND). The fifth switch SW5 is coupled between the input node 34 and the output node 36. The sixth switch SW6 is coupled between the output node 36 and the GND. The MCP 30 also includes a fly capacitor C_{FLY} that is coupled between the first intermediate node n1 and the second intermediate node n2.

As shown, the input node 34 is coupled directly to the battery 20 without any intervening circuit. Accordingly, the first switch SW1, the third switch SW3, and the fifth switch SW5 are coupled directly to the battery 20 via the input node 34. In this regard, each of the first switch SW1, the third switch SW3, and the fifth switch SW5 will be one of the measurement nodes 18 in FIG. 2.

Accordingly, one or more of the current sense circuits 22(1)-22(N) (not shown) can be coupled to the first switch SW1, the third switch SW3, and the fifth switch SW5 to measure battery currents I_{SW1}, I_{SW3}, I_{SW5} that flow through the first switch SW1, the third switch SW3, and the fifth switch SW5, respectively.

The MCP 30 may operate in a buck mode to output the low-frequency voltage V_{DC} as zero volt (0 V) or V_{BAT}, or in a boost mode to output the low-frequency voltage V_{DC} as 2×V_{BAT}. Specifically, to output the low-frequency voltage V_{DC} as 0 V, the sixth switch SW6 is closed while all other switches (SW1, SW2, SW3, SW4, SW5) are opened. To output the low-frequency voltage V_{DC} as VBAT, the fifth switch SW5 is closed while all other switches (SW1, SW2, SW3, SW4, SW6) are opened. To output the low-frequency voltage V_{DC} as 2×V_{BAT}, the first switch SW1 and the fourth switch SW4 are first closed, while all other switches (SW2, SW3, SW5, SW6) are opened, to charge the fly capacitor C_{FLY} to the battery voltage V_{BAT} at the first intermediate node n1. Subsequently, the second switch SW2 and the fourth switch SW4 are closed, while all other switches (SW1, SW3, SW5, SW6) are opened, to thereby output the low-frequency voltage V_{DC} as 2×V_{BAT}. Thus, by toggling the low-frequency voltage V_{DC} between 0 V, V_{BAT}, and/or 2×V_{BAT} based on a specific duty cycle (e.g., 10% at 0 V, 50% at V_{BAT}, and 40% at 2×V_{BAT}), the MCP 30 may output the low-frequency voltage V_{DC} at any desirable level to thereby adjust the low-frequency current I_{DC}.

Taking the boost mode operation (V_{DC}=2×V_{BAT}) as an example, when the first switch SW1 and the fourth switch SW4 are closed to charge the fly capacitor C_{FLY}, only the battery current I_{SW1} flowing through the first switch SW1 will be measured since the third switch SW3 and the fifth switch SW5 are both opened. Subsequently, when the second switch SW2 and the third switch SW3 are closed to output the low-frequency voltage at 2×V_{BAT}, only the battery current I_{SW3} flowing through the third switch SW3 will be measured since the first switch SW1 and the fifth switch SW5 are both opened. Accordingly, an average battery current measured during the boost mode operation will be an average of the battery currents I_{SW1} and I_{SW3}. Understandably, when the MCP 30 alternates the low-frequency voltage V_{DC} between 0 V, V_{BAT}, and 2×V_{BAT} based on a defined duty cycle, the measured average battery current will be an average of the battery currents I_{SW1}, I_{SW3}, I_{SW5} as measured in one or more duty cycles.

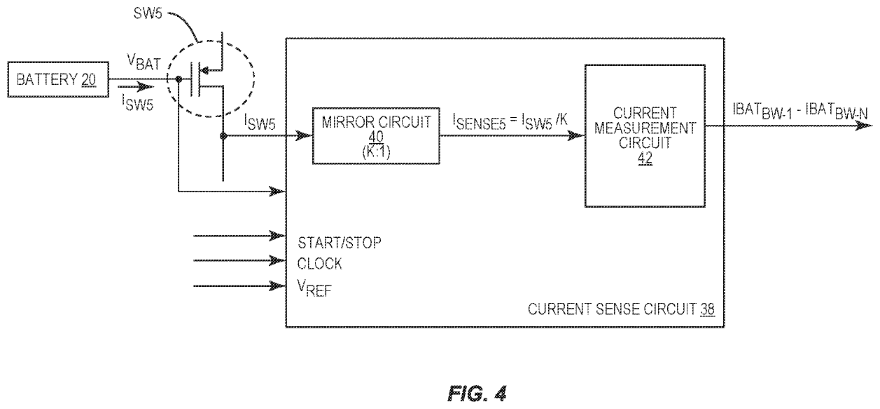

FIG. 4 is a schematic diagram of an exemplary current sense circuit 38 that can be provided in the electrical circuit 16 in FIG. 2 as any of the current sense circuits 22(1)-22(N). Common elements between FIGS. 2, 3, and 4 are shown therein with common element numbers and will not be re-described herein.

In an embodiment, the current sense circuit 38 can include a mirror circuit 40 and a current measurement circuit 42. As an example, the current sense circuit 38 is coupled to the fifth switch SW5 in FIG. 3 to measure the battery current I_{SW5} that flows through the fifth switch SW5 when the MCP 30 outputs the low-frequency voltage V_{DC} at V_{BAT}.

In this regard, the mirror circuit 40 is coupled to the fifth switch SW5 and configured to generate a sensed current I_{SENSE5} that is proportionally related to the battery current I_{SW5} flowing through the fifth switch SW5. In an embodiment, the mirror circuit 40 can be a K-to-1 (K:1) (K>1) mirror circuit that scales the battery current I_{SW5} down to the sensed current I_{SENSE5} (I_{SENSE5}=I_{SW5}/K).

The current measurement circuit 42 is coupled to the mirror circuit 40. More specifically, the current measurement circuit 42 is configured to generate the respective one of the digital measurement words IBAT_{BW-1}-IBAT_{BW-N} to an average of the sensed current I_{SENSE5} flowing through the third switch SW3 during the selected measurement period. In an embodiment, the current measurement circuit 42 may operate based on a start/stop signal, a clock signal, and a reference voltage V_{REF} to generate the respective one of the digital measurement words IBAT_{BW-1}-IBAT_{BW-N} based on the sensed current I_{SENSE5}. For specific embodiments and an in-depth discussion of the current measurement circuit 42, please refer to U.S. Pat. No. 11,268,990 B2, entitled “CURRENT MEASUREMENT CIRCUIT FOR OPTIMIZATION OF POWER CONSUMPTION IN ELECTRONIC DEVICES.”

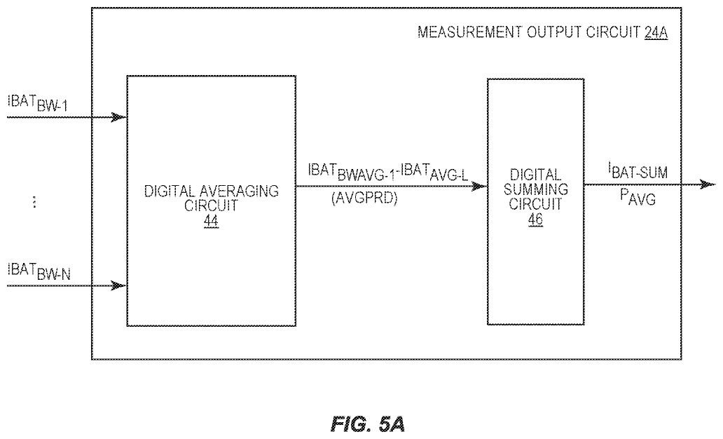

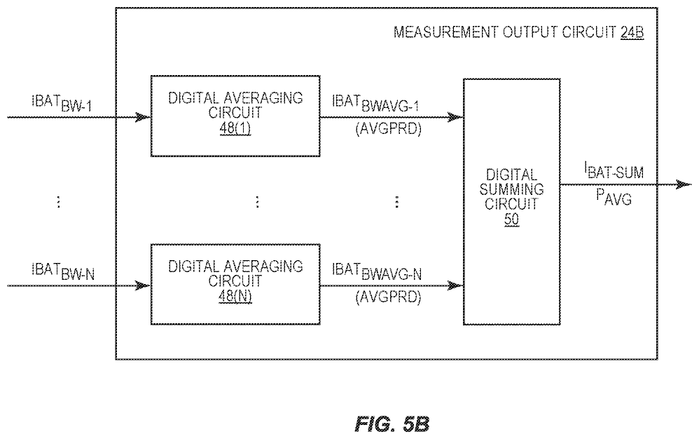

FIGS. 5A and 5B are schematic diagrams each providing an exemplary illustration of the measurement output circuit 24 configured according to an embodiment of the present disclosure. Common elements between FIGS. 2 and 5A-5B are shown therein with common element numbers and will not be re-described herein.

FIG. 5A illustrates an exemplary measurement output circuit 24A configured according to one embodiment of the present disclosure. Herein, the measurement output circuit 24A includes a digital averaging circuit 44 and a digital summing circuit 46. The digital averaging circuit 44 is coupled to the current sense circuits 22(1)-22(N) to receive the digital measurement words IBAT_{BW-1}-IBAT_{BW-N} in the selected measurement period. Accordingly, the digital averaging circuit 44 averages the digital measurement words IBAT_{BW-1}-IBAT_{BW-N} over multiple selected measurement periods to generate multiple averaged digital measurement words IBAT_{BWAVG-1}-IBAT_{BWAVG-L}. The digital summing circuit 46, which can be an infinite impulse response (IIR) of a finite impulse response (FIR) filter, as an example, is configured to average the averaged digital measurement words IBAT_{BWAVG-}1-IBAT_{BWAVG-L} over an averaging period (AVGPRD) to thereby generate the summarized measurement result I_{BAT-SUM}.

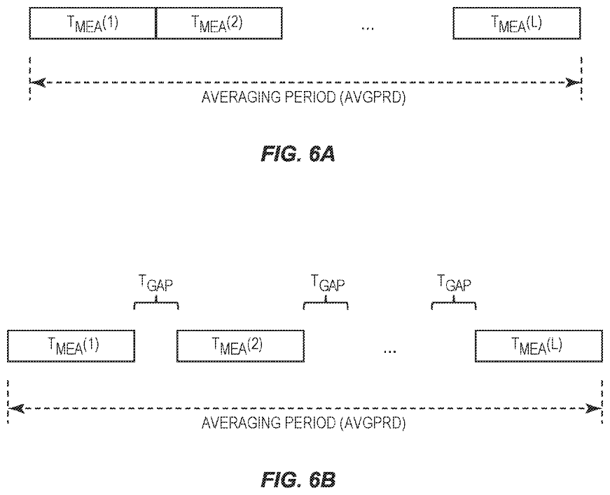

FIGS. 6A and 6B are schematic diagrams providing exemplary illustrations of the averaging period (AVGPRD) as defined according to different embodiments of the present disclosure.

As shown in FIG. 6A, the averaging period (AVGPRD) can include multiple continuous measurement periods T_{MEA}(1)-T_{MEA}(L). In an embodiment, L is an integer number that equals a power of two (L=2, 4, 8, 16, . . . ). Herein, each of the measurement periods T_{MEA}(1)-T_{MEA}(L) can be equated with the selected measurement period described above. As such, the averaging period (AVGPRD) includes multiple selected measurement periods T_{MEA}(1)-T_{MEA}(L) and thus has a longer duration than each of the selected measurement periods T_{MEA}(1)-T_{MEA}(L).

In contrast, as shown in FIG. 6B, the averaging period (AVGPRD) can include multiple non-continuous measurement periods T_{MEA}(1)-T_{MEA}(L) that are each separated by a gap interval T_{GAP}. In this regard, the averaging period (AVGPRD) includes not only measurement periods T_{MEA}(1)-T_{MEA}(L) but also the gap interval T_{GAP}.

With reference back to FIG. 5A, the digital averaging circuit 44 is thus configured to generate each of the averaged digital measurement words IBAT_{BWAVG-1}-IBAT_{BWAVG-L} in a respective one of the continuous measurement periods T_{MEA}(1)-T_{MEA}(L) in FIG. 6A or in a respective one of the non-continuous measurement periods T_{MEA}(1)-T_{MEA}(L) in FIG. 6B. Accordingly, the digital summing circuit 46 will generate the summarized measurement result I_{BAT-SUM} over the entire averaging period (AVGPRD).

FIG. 5B illustrates an exemplary measurement output circuit 24B configured according to one embodiment of the present disclosure. Herein, the measurement output circuit 24B includes multiple digital averaging circuits 48(1)-48(N) and a digital summing circuit 50, which can be an IIR or an FIR filter, as an example. Each of the digital averaging circuits 48(1)-48(N) is coupled to a respective one of the current sense circuits 22(1)-22(N) to receive a respective one of the digital measurement words IBAT_{BW-1}-IBAT_{BW-N}.

According to an embodiment of the present disclosure, each of the digital averaging circuits 48(1)-48(N) is configured to average the respective one of the digital measurement words IBAT_{BW-1}-IBAT_{BW-N} over the averaging period (AVGPRD) to thereby generate a respective one of multiple averaged digital measurement words IBAT_{BWAVG-1}-IBAT_{BWAVG-N}. The digital summing circuit 50 is configured to summarize the averaged digital measurement words IBAT_{BWAVG-1}-IBAT_{BWAVG-N} to thereby generate the summarized measurement result I_{BAT-SUM}. Notably, since each of the averaged digital measurement words IBAT_{BWAVG-1}-IBAT_{BWAVG-N} reflects an average current over the averaging period (AVGPRD), the summarized measurement result IBAT-SUM will likewise reflect a sum of averaged current in the battery 20 over the averaging period (AVGPRD).

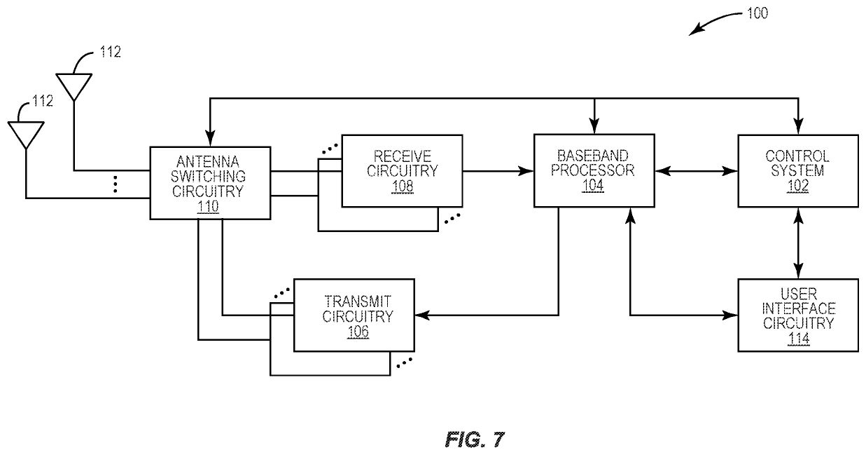

The electrical circuit 16 of FIG. 2 can be provided in a user element to support the embodiments described above. In this regard, FIG. 7 is a schematic diagram of an exemplary user element 100 wherein the electrical circuit 16 of FIG. 2 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

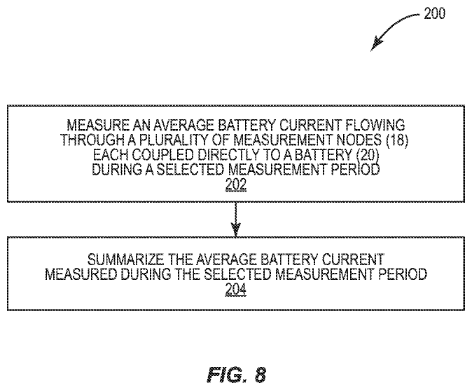

In an embodiment, the electrical circuit 16 in FIG. 2 can be configured to measure the average battery current IBAT according to a process. In this regard, FIG. 8 is a flowchart of an exemplary process 200 for measuring the average battery current IBAT in the electrical circuit 16.

Herein, the current sense circuits 22(1)-22(N) are each configured to measure the average battery current I_{BAT-1}-I_{BAT-M} flowing through the respective one or more of the measurement nodes 18, each coupled directly to the battery 20, during the selected measurement period (step 202). The measurement output circuit 24 is configured to summarize the average battery currents I_{BAT-1}-I_{BAT-M} measured during the selected measurement period (step 204).

Those skilled in the art will recognize improvements and modifications to the preferred embodiments of the present disclosure. All such improvements and modifications are considered within the scope of the concepts disclosed herein and the claims that follow.

1. An electrical circuit comprising:
a plurality of measurement nodes each coupled directly to a battery;
one or more current sense circuits each coupled to a respective one or more of the plurality of measurement nodes and configured to measure an average battery current flowing through the respective one or more of the plurality of measurement nodes during a selected measurement period; and
a measurement output circuit configured to summarize the average battery current measured by each of the one or more current sense circuits during the selected measurement period.

2. The electrical circuit of claim 1, wherein the selected measurement period can be a duration of one of:
a time-division duplex (TDD) timeslot;
a TDD mini timeslot;
a plurality of TDD timeslots; and
a plurality of TDD mini timeslots.

3. The electrical circuit of claim 1, wherein each of the one or more current sense circuits is further configured to generate a respective one of one or more digital measurement words indicating the average battery current measured during the selected measurement period.

4. The electrical circuit of claim 3, wherein each of the one or more current sense circuits comprises:
a mirror circuit coupled to at least one of the respective one or more of the plurality of measurement nodes and configured to generate a sensed current proportionally related to a battery current flowing through the at least one of the respective one or more of the plurality of measurement nodes during the selected measurement period; and
a current measurement circuit coupled to the mirror circuit and configured to generate the respective one of the one or more digital measurement words indicating an average of the sensed current flowing through the at least one of the respective one or more of the plurality of measurement nodes during the selected measurement period.

5. The electrical circuit of claim 4, wherein the mirror circuit is further configured to scale down the battery current to generate the sensed current.

6. The electrical circuit of claim 3, wherein the measurement output circuit is further configured to generate a digital summary word comprising a sum of the one or more digital measurement words.

7. The electrical circuit of claim 6, wherein the measurement output circuit is further configured to determine an average power consumption during the selected measurement period.

8. The electrical circuit of claim 3, wherein the measurement output circuit comprises:
a digital averaging circuit configured to average the one or more digital measurement words in each of multiple measurement periods in an averaging period to thereby generate a respective one of multiple averaged digital measurement words during the averaging period; and
a digital summing circuit configured to summarize the multiple averaged digital measurement words to thereby generate the summarized measurement result over the averaging period.

9. The electrical circuit of claim 3, wherein the measurement output circuit comprises:
a plurality of digital averaging circuits each configured to average a respective one of the one or more digital measurement words indicating the average battery current over an averaging period to thereby generate a respective one of one or more averaged digital measurement words; and
a digital summing circuit configured to summarize the one or more averaged digital measurement words to thereby generate the summarized measurement result over the averaging period.

10. The electrical circuit of claim 8, wherein the averaging period comprises a plurality of continuous measurement periods.

11. The electrical circuit of claim 8, wherein the averaging period comprises a plurality of non-continuous measurement periods.

12. The electrical circuit of claim 1, wherein each of the one or more current sense circuits is further configured to periodically measure the average battery current flowing through the respective one or more of the plurality of measurement nodes.

13. The electrical circuit of claim 1, wherein each of the one or more current sense circuits is further configured to:
start measuring the average battery current flowing through the respective one or more of the plurality of measurement nodes in response to a start signal; and
stop measuring the average battery current flowing through the respective one or more of the plurality of measurement nodes in response to a stop signal.

14. The electrical circuit of claim 1, further comprising a multi-level charge pump, MCP, couped in series to a power inductor, the MCP comprises:
an input node coupled to the battery without any intervening circuit;
an output node coupled to the power inductor;
a first intermediate node;
a second intermediate node;
a first switch coupled between the input node and the first intermediate node;
a second switch coupled between the first intermediate node and the output node;
a third switch coupled between the input node and the second intermediate node;
a fourth switch coupled between the second intermediate node and a ground;
a fifth switch coupled between the input node and the output node; and
a sixth switch coupled between the output node and the ground.

15. The electrical circuit of claim 14, wherein:
the plurality of measurement nodes comprises the first switch, the third switch, and the fifth switch; and
the one or more current sense circuits are each coupled to a respective one of the first switch, the third switch, and the fifth switch and configured to measure the average battery current flowing through the respective one of the first switch, the third switch, and the fifth switch during the selected measurement period when the respective one of the first switch, the third switch, and the fifth switch is closed.

16. A method for measuring an average battery current in an electrical circuit comprising:
measuring the average battery current flowing through a plurality of measurement nodes each coupled directly to a battery during a selected measurement period; and
summarizing the average battery current measured during the selected measurement period.

17. The method of claim 16, further comprising measuring the average battery current during the selected measurement period that is a duration of one of:
a time-division duplex (TDD) timeslot;
a TDD mini timeslot;
a plurality of TDD timeslots; and
a plurality of TDD mini timeslots.

18. The method of claim 16, further comprising generating a respective one of one or more digital measurement words indicating the average battery current measured during the selected measurement period.

19. The method of claim 18, further comprising:
generating a sensed current proportionally related to a battery current flowing through the at least one of the respective one or more of the plurality of measurement nodes during the selected measurement period; and
generating the respective one of the one or more digital measurement words indicating an average of the sensed current flowing through the at least one of the respective one or more of the plurality of measurement nodes during the selected measurement period.

20. The method of claim 19, further comprising scaling down the battery current to generate the sensed current.

21. The method of claim 18, further comprising generating a digital summary word comprising a sum of the one or more digital measurement words.

22. The method of claim 21, further comprising determining an average power consumption during the selected measurement period.

23. The method of claim 18, further comprising:
averaging the one or more digital measurement words in each of multiple measurement periods in an averaging period to thereby generate a respective one of multiple averaged digital measurement words during the averaging period; and
summarizing the multiple averaged digital measurement words to thereby generate the summarized measurement result over the averaging period.

24. The method of claim 18, further comprising:
averaging a respective one of the one or more digital measurement words indicating the average battery current over an averaging period to thereby generate a respective one of one or more averaged digital measurement words; and
summarizing the one or more averaged digital measurement words to thereby generate the summarized measurement result over the averaging period.

25. The method of claim 23, further comprising dividing the averaging period into a plurality of continuous measurement periods.

26. The method of claim 23, further comprising dividing the averaging period into a plurality of non-continuous measurement periods.

27. The method of claim 16, further comprising periodically measuring the average battery current flowing through the respective one or more of the plurality of measurement nodes.

28. The method of claim 16, further comprising:
starting the measuring of the average battery current flowing through the respective one or more of the plurality of measurement nodes in response to a start signal; and
stopping the measuring of the average battery current flowing through the respective one or more of the plurality of measurement nodes in response to a stop signal.
